(19) United States
(12) Patent Application Publication
(10) Pub. No.: US 2023/0188726 A1
(43) Pub. Date: Jun. 15, 2023

(54) Dynamic Method for Symbol Encoding

(71) Applicant: Google LLC, Mountain View, CA (US)

(72) Inventors: Vincent Rabaud, Paris (FR); Maryla Ustarroz-Calonge, Paris (FR)

(21) Appl. No.: 17/922,306

(22) PCT Filed: Jun. 16, 2020
(86) PCT No.: PCT/US2020/037927

§ 371 Date: Oct. 28, 2022

(51) Int. Cl. H04N 19/149; H04N 19/182; H04N 19/186; H04N 19/46

(52) U.S. Cl. CPC H04N 19/149; H04N 19/182; H04N 19/186; H04N 19/46

(57) ABSTRACT

Encoding an image includes determining respective costs of coding a symbol using available coding types. A first coding type indicates that a value of the symbol is to be decoded using a same number of bits, and a second coding type indicates that the value of the symbol is to be decoded using a range. An optimal coding type of the available coding types is selected, which corresponds to a smallest cost of the respective costs. A first indicator of the optimal coding type and a first symbol value of the symbol using the optimal coding type are encoded in a compressed bitstream. Decoding an image includes decoding, from a header of a compressed bitstream, respective coding types of symbols encoded in the compressed bitstream and decoding, from the compressed bitstream, respective values of the symbols according to the respective coding types decoded from the header.

### BACKGROUND

Image content (e.g., still images or frames of video) represents a significant amount of online content. For example, a web page may include multiple images, and a large portion of the time and resources spent rendering the web page are dedicated to rendering those images for display. The amount of time and resources required to receive and render an image for display depends in part on the manner in which the image is compressed. As such, an image can be rendered faster by reducing the total data size of the image using compression and decompression techniques.

Different compression techniques can be used to compress (at an encoder) and corresponding decompression techniques can be used to decompress at a decoder for different types of data. For example, techniques such as Huffman coding, Lempel-Ziv-Welch compression, run-length encoding, Golomb coding, arithmetic coding, and the like can be used.

### SUMMARY

A first aspect is a method of encoding symbols representing information of an image. The method includes determining respective costs of coding a symbol using available coding types, the available coding types include a first coding type and a second coding type, the first coding type indicates that a value of the symbol is to be decoded using a same number of bits, and the second coding type indicates that the value of the symbol is to be decoded using a range; selecting an optimal coding type of the available coding types, where the optimal coding type corresponds to a smallest cost of the respective costs; encoding, in a compressed bitstream, a first indicator of the optimal coding type; and encoding, in the compressed bitstream, a first symbol value of the symbol using the optimal coding type.

A second aspect is an apparatus for decoding an image. The apparatus includes a memory and a processor. The processor is configured to execute instructions stored in the memory to decode, from a header of a compressed bitstream of the image, respective coding types of symbols encoded in the compressed bitstream, where a respective coding type of the respective coding types indicates how a value of a symbol encoded according to the respective coding type is to be decoded, the respective coding types include a first coding type and a second coding type, the first coding type indicates that the value of the symbol is to be decoded using a same number of bits, and the second coding type indicates that the value of the symbol is to be decoded using a range; and reconstruct the image by instructions to: decode, from the compressed bitstream, respective values of the symbols according to the respective coding types decoded from the header.

A third aspect is a method of decoding an image from a compressed bitstream. The method includes decoding, from a header of the compressed bitstream of the image, respective coding types of symbols encoded in the compressed bitstream; and decoding, from the compressed bitstream, respective values of the symbols according to the respective coding types decoded from the header.

These and other aspects of the present disclosure are disclosed in the following detailed description of the embodiments, the appended claims, and the accompanying figures.

It will be appreciated that aspects can be implemented in any convenient form. For example, aspects may be implemented by appropriate computer programs which may be carried on appropriate carrier media which may be tangible carrier media (e.g., disks) or intangible carrier media (e.g., communications signals). Aspects may also be implemented using suitable apparatus which may take the form of programmable computers running computer programs arranged to implement the methods and/or techniques disclosed herein. Aspects can be combined such that features described in the context of one aspect may be implemented in another aspect.

### BRIEF DESCRIPTION OF THE DRAWINGS

FIG. 1 is a diagram of a computing device in accordance with implementations of this disclosure.

FIG. 2 is a diagram of a computing and communications system in accordance with implementations of this disclosure.

FIG. 3 is a diagram of a video stream for use in encoding and decoding in accordance with implementations of this disclosure.

FIG. 4 is a block diagram of an encoder in accordance with implementations of this disclosure.

FIG. 5 is a block diagram of a decoder in accordance with implementations of this disclosure.

FIG. 6 is an example of a flowchart of a technique for encoding symbols according to implementations of this disclosure.

FIG. 7 is an example of a flowchart of a technique for decoding symbols according to implementations of this disclosure.

FIG. 8 illustrates examples of always using a same coding type to code a symbol according to traditional coding of symbols

### DETAILED DESCRIPTION

Media data (e.g., a standalone image, a frame of a video, video, audio, speech, documents, etc.) coding (e.g., compression) includes converting the media data into a sequence of meaningful parts (e.g., syntax elements, symbol values, etc.) according to a predetermined structure and semantics. The sequence of the symbol values can be written to, or transmitted in, a compressed bitstream according to the predetermined structure.

The syntax elements can represent any aspect of the media data. For example, with respect to image data, a first symbol can represent the width of the image, a second symbol can represent the size of a certain transform block, and a third symbol can represent a given color channel value (e.g., a luminance value, a U chrominance value, a red color value, or another color channel value) of a pixel. Other examples of symbols can include block coding mode, reference picture indexes (in the case of inter-prediction), motion vector offsets, motion vector differences, quantization parameters, quantized transform coefficient values, quantized transform coefficient levels, etc. For other media types (e.g., audio, speech, text, document, or other data types) different symbols are possible. Some symbols can have one value in the compressed bitstream. Some symbols can have more than one value in the compressed bitstream. For example, each pixel of the image can have a respective symbol value for its luminance value. For example, at least some of the quantized transform coefficients of a quantized transform block can be represented by one or more respective symbol values in the compressed bitstream.

Each symbol value is written to the compressed stream according to a pre-determined type (e.g., format) of that symbol that is set (e.g., defined) in the predetermined structure. The predetermined structure typically defines the symbol semantics and formats so that a decoder of the compressed bitstream can decode symbol values of the symbol according to the pre-determined type.

Without limiting the disclosure herein in any way, examples of pre-determined types can include one or more of 1) an unsigned n-bit number appearing directly in the compressed bitstream where the bits can be read from high to low order; 2) a variable length unsigned n-bit number appearing directly in the compressed bitstream; 3) an unsigned little-endian n-byte number appearing directly in the compressed bitstream; 4) an unsigned integer represented by a variable number of little-endian bytes; 5) a signed integer that is converted from an n-bits unsigned integer in the compressed bitstream; 6) an unsigned encoded integer with a maximum number of values n where the read symbol value from the compressed bitstream is in range 0 . . . n-1; 7) a literal that is an unsigned arithmetic encoded n-bit number encoded as n flags; 8) an arithmetic encoded symbol that is coded from a small alphabet (e.g., of at most 16 entries) where the symbol is decoded based on a context sensitive Cumulative Distribution Function (CDF); or 9) an unsigned arithmetic encoded integer with maximum number of values n. Other pre-determined types are possible.

Each symbol value can be converted to a binary string and encoded according to the pre-determined coding type of the symbol. The binarization scheme can be different for different symbols. For example, the binarization scheme for a symbol can depend on the set of possible symbol values or other properties of the symbol. Examples of coding types include Golomb coding, Exp-Golomb coding, arithmetic coding, asymmetric numeral systems (ANS), differential coding, Huffman coding, run length encoding (RLE), variable-length-to-variable-length (“V2V”) coding, variable-length-to-fixed-length (“V2F”) coding, Limpel-Ziv (LZ) coding, dictionary coding, probability interval partitioning entropy coding (“PIPE”). Other coding types are also possible.

To summarize, there are traditionally different ways (e.g., coding types) to encode symbols (e.g., values of the symbols). The coding type is typically preset by an encoder and a decoder.

A first coding type can be to code with a same number of bits. That is, for a given symbol value, an encoder can write and a decoder can read the next n (e.g., 8) number of bits. For example, if a symbol value is known to fit in 8-bits, such as a value that is between 0 and 255, then the symbol value can be coded using 8 bits. A second coding type can be to code using a range. For example, the second coding type can be more efficient than the first coding type when it is known that the width of a symbol is, for example, between 0 and 2ⁿ-1 (e.g., between 0 and 255, where n=8) but some smaller range (e.g., between 0 and 200) that does not require an even number of bits (e.g., a number of bits that is not n). The first coding type and the second coding type can be referred to as fixed-number-of-bits coding types. Other fixed-number-of-bits coding types are possible.

A third coding type can be to code using static or updatable probabilities that are defined in a histogram of the symbol values. When the distribution of the symbol values is known, fewer bits can be used for coding more frequently occurring symbol values and more bits can be used for coding less frequently occurring symbol values. For example, a Huffman tree can be used to code the symbol values of the symbol. A fourth coding type can be to code using a Golomb scheme, which can be useful when the occurrence of small symbol values is significantly more likely than large symbol values. For example, given a number of codes, first bits of the number can be coded in a certain way and the remaining bits can be coded as raw bits (i.e., as a series of 0s and 1s). The third coding type and the fourth coding type can be referred to as variable-number-of-bits coding types. Other variable-number-of-bits coding types are possible.

FIG. 8 illustrates examples 800 of always using a same coding type to code a symbol according to traditional coding of symbols. The examples 800 include code snippet 802-and code snippet 804 extracted from the High Efficiency Video Coding (HEVC) specification. The examples 800 are described with the respect to the symbols pcm_flag, pcm_alignment_zero_bit, leading_zero_8bits, and start_code_prefix_one_3bytes. These symbols are used as mere instructive examples and are not intended to limit the disclosure herein in any way.

A row 806 shows that the symbol value pcm_flag[x0][y0] is always read from a compressed bitstream as a context-adaptive arithmetic entropy-coded syntax element (i.e., using the coding type ae(v)). A row 808 shows that the symbol pcm_alignment_zero_bit is always read from the compressed bitstream using a fixed-pattern bit string using 1 bit (i.e., using the coding type f(n)). A row 810 shows that the symbol leading_zero_8bits is always read from the compressed bitstream as a fixed-pattern bit string using 8 bits written (from left to right) with the left bit first (i.e., using the coding type f(n)). A row 812 shows that the symbol start_code_prefix_one_3bytes is always read from the compressed bitstream as a fixed-pattern bit string using 24 bits written (from left to right) with the left bit first (i.e., using the coding type f(n)).

However, always using the same coding type to code a symbol (i.e., to code the symbol values of the symbol) may not result in the most optimal compression. Depending on the statistics of the symbol, one of the possible available coding types can perform much better than a pre-specified, and fixed coding type of the symbol.

Implementations according to this disclosure can dynamically determine the respective optimal coding of symbols. That is, rather than pre-specify the coding type for a symbol, the optimal type for encoding symbol values of a symbol can be determined by an encoder at runtime (e.g., as an encoder is compressing/encoding a media stream/file). The encoder can communicate the coding type in the header of a compressed bitstream. A decoder can decode the symbol values using the coding type communicated in the header.

As such, implementations according to this disclosure can dynamically indicate the coding type of that symbol. Before reading symbols, a decoder reads the coding types of those symbols. For at least some coding types, the encoder can write into, and a decoder can read from, the header of the compressed bitstream additional parameters of the coding type. For example, if a symbol is indicated as to be decoded using a coding type that uses histogram probabilities, then the parameters of the coding type can include a dictionary of symbols in the header of the compressed bitstream.

Such flexibility in determining and communicating symbol coding types can provide more adaptability to the symbols and, therefore, greater compression at the extra cost of only storing the coding types of the symbols and the header. In some situations, the parameters of the coding type can already be stored in the decoder. In some other situations, if the coding type were forced (e.g., pre-defined, pre-specified, fixed, etc.), the parameters would already be stored. The coding type can be forced, for example, in a situation where a symbol always has one coding type. In another example, the coding type can be forced when a configuration is already known. For example, a configuration where a small image is being encoded forces the constraint that a first symbol is of a certain first coding type, a second symbol is of certain second coding type, and so on.

Details of the dynamic method for symbol encoding are described herein with initial reference to a system in which the teachings herein can be implemented.

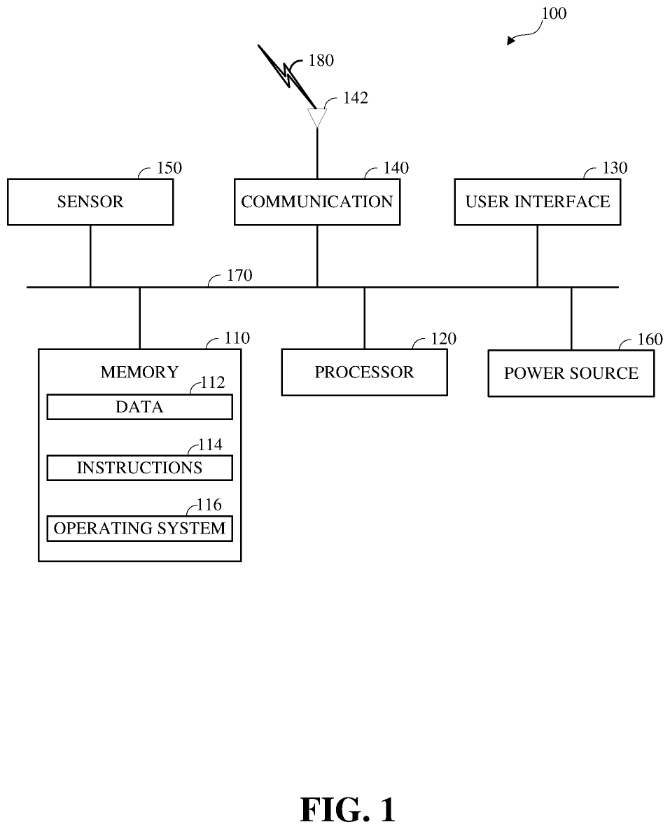

FIG. 1 is a diagram of a computing device 100 in accordance with implementations of this disclosure. The computing device 100 shown includes a memory 110, a processor 120, a user interface (UI) 130, an electronic communication unit 140, a sensor 150, a power source 160, and a bus 170. As used herein, the term “computing device” includes any unit, or combination of units, capable of performing any method, or any portion or portions thereof, disclosed herein.

The computing device 100 may be a stationary computing device, such as a personal computer (PC), a server, a workstation, a minicomputer, or a mainframe computer; or a mobile computing device, such as a mobile telephone, a personal digital assistant (PDA), a laptop, or a tablet PC. Although shown as a single unit, any one element or elements of the computing device 100 can be integrated in any number of separate physical units. For example, the user interface 130 and processor 120 can be integrated in a first physical unit, and the memory 110 can be integrated in a second physical unit.

The memory 110 can include any non-transitory computer-usable or computer-readable medium, such as any tangible device that can, for example, contain, store, communicate, or transport data 112, instructions 114, an operating system 116, or any information associated therewith, for use by or in connection with other components of the computing device 100. The non-transitory computer-usable or computer-readable medium can be, for example, a solid state drive, a memory card, removable media, a read-only memory (ROM), a random-access memory (RAM), any type of disk including a hard disk, a floppy disk, an optical disk, a magnetic or optical card, an application-specific integrated circuit (ASIC), or any type of non-transitory media suitable for storing electronic information, or any combination thereof.

Although shown as a single unit, the memory 110 may include multiple physical units, such as one or more primary memory units, such as random-access memory units, one or more secondary data storage units, such as disks, or a combination thereof. For example, the data 112, or a portion thereof, the instructions 114, or a portion thereof, or both, may be stored in a secondary storage unit and may be loaded or otherwise transferred to a primary storage unit in conjunction with processing the respective data 112, executing the respective instructions 114, or both. In some implementations, the memory 110, or a portion thereof, may be removable memory.

The data 112 can include information, such as input audio and/or visual data, encoded audio and/or visual data, decoded audio and/or visual data, or the like. The visual data can include still images, frames of video sequences, and/or video sequences. The instructions 114 can include directions, such as code, for performing any method, or any portion or portions thereof, disclosed herein. The instructions 114 can be realized in hardware, software, or any combination thereof. For example, the instructions 114 may be implemented as information stored in the memory 110, such as a computer program, that may be executed by the processor 120 to perform any of the respective methods, algorithms, aspects, or combinations thereof, as described herein.

Although shown as included in the memory 110, in some implementations, the instructions 114, or a portion thereof, may be implemented as a special-purpose processor, or circuitry, that can include specialized hardware for carrying out any of the methods, algorithms, aspects, or combinations thereof, as described herein. Portions of the instructions 114 can be distributed across multiple processors on the same machine or different machines or across a network, such as a local area network, a wide area network, the Internet, or a combination thereof.

The processor 120 can include any device or system, now-existing or hereafter developed, capable of manipulating or processing a digital signal or other electronic information, including optical processors, quantum processors, molecular processors, or a combination thereof. For example, the processor 120 can include a special-purpose processor, a central processing unit (CPU), a digital signal processor (DSP), a plurality of microprocessors, one or more microprocessors in association with a DSP core, a controller, a microcontroller, an Application Specific Integrated Circuit (ASIC), a Field Programmable Gate Array (FPGA), a programmable logic array, a programmable logic controller, microcode, firmware, any type of integrated circuit (IC), a state machine, or any combination thereof. As used herein, the term “processor” includes a single processor or multiple processors.

The user interface 130 can include any unit capable of interfacing with a user, such as a virtual or physical keypad, a touchpad, a display, a touch display, a speaker, a microphone, a video camera, a sensor, or any combination thereof. For example, the user interface 130 may be an audio-visual display device, and the computing device 100 may present audio, such as decoded audio, using the user interface 130 audio-visual display device, such as in conjunction with displaying video, such as decoded video. Although shown as a single unit, the user interface 130 may include one or more physical units. For example, the user interface 130 may include an audio interface for performing audio communication with a user, and a touch display for performing visual and touch-based communication with the user.

The electronic communication unit 140 can transmit, receive, or transmit and receive signals via a wired or wireless electronic communication medium 180, such as a radio frequency (RF) communication medium, an ultraviolet (UV) communication medium, a visible light communication medium, a fiber-optic communication medium, a wireline communication medium, or a combination thereof. For example, as shown, the electronic communication unit 140 is operatively connected to an electronic communication interface 142, such as an antenna, configured to communicate via wireless signals.

Although the electronic communication interface 142 is shown as a wireless antenna in FIG. 1, the electronic communication interface 142 can be a wireless antenna, as shown, a wired communication port, such as an Ethernet port, an infrared port, a serial port, or any other wired or wireless unit capable of interfacing with a wired or wireless electronic communication medium 180. Although FIG. 1 shows a single electronic communication unit 140 and a single electronic communication interface 142, any number of electronic communication units and any number of electronic communication interfaces can be used.

The sensor 150 may include, for example, an audio-sensing device, a visible light-sensing device, a motion-sensing device, or a combination thereof. For example, the sensor 150 may include a sound-sensing device, such as a microphone, or any other sound-sensing device, now existing or hereafter developed, that can sense sounds in the proximity of the computing device 100, such as speech or other utterances, made by a user operating the computing device 100. In another example, the sensor 150 may include a camera, or any other image-sensing device, now existing or hereafter developed, that can sense an image, such as the image of a user operating the computing device. Although a single sensor 150 is shown, the computing device 100 may include a number of sensors 150. For example, the computing device 100 may include a first camera oriented with a field of view directed toward a user of the computing device 100 and a second camera oriented with a field of view directed away from the user of the computing device 100.

The power source 160 can be any suitable device for powering the computing device 100. For example, the power source 160 can include a wired external power source interface; one or more dry cell batteries, such as nickel-cadmium (NiCd), nickel-zinc (NiZn), nickel metal hydride (NiMH), lithium-ion (Li-ion); solar cells; fuel cells; or any other device capable of powering the computing device 100. Although a single power source 160 is shown in FIG. 1, the computing device 100 may include multiple power sources 160, such as a battery and a wired external power source interface.

Although shown as separate units, the electronic communication unit 140, the electronic communication interface 142, the user interface 130, the power source 160, or portions thereof, may be configured as a combined unit. For example, the electronic communication unit 140, the electronic communication interface 142, the user interface 130, and the power source 160 may be implemented as a communications port capable of interfacing with an external display device, providing communications, power, or both.

One or more of the memory 110, the processor 120, the user interface 130, the electronic communication unit 140, the sensor 150, or the power source 160 may be operatively coupled via a bus 170. Although a single bus 170 is shown in FIG. 1, a computing device 100 may include multiple buses. For example, the memory 110, the processor 120, the user interface 130, the electronic communication unit 140, the sensor 150, and the bus 170 may receive power from the power source 160 via the bus 170. In another example, the memory 110, the processor 120, the user interface 130, the electronic communication unit 140, the sensor 150, the power source 160, or a combination thereof, may communicate data, such as by sending and receiving electronic signals, via the bus 170.

Although not shown separately in FIG. 1, one or more of the processor 120, the user interface 130, the electronic communication unit 140, the sensor 150, or the power source 160 may include internal memory, such as an internal buffer or register. For example, the processor 120 may include internal memory (not shown) and may read data 112 from the memory 110 into the internal memory (not shown) for processing.

Although shown as separate elements, the memory 110, the processor 120, the user interface 130, the electronic communication unit 140, the sensor 150, the power source 160, and the bus 170, or any combination thereof, can be integrated in one or more electronic units, circuits, or chips.

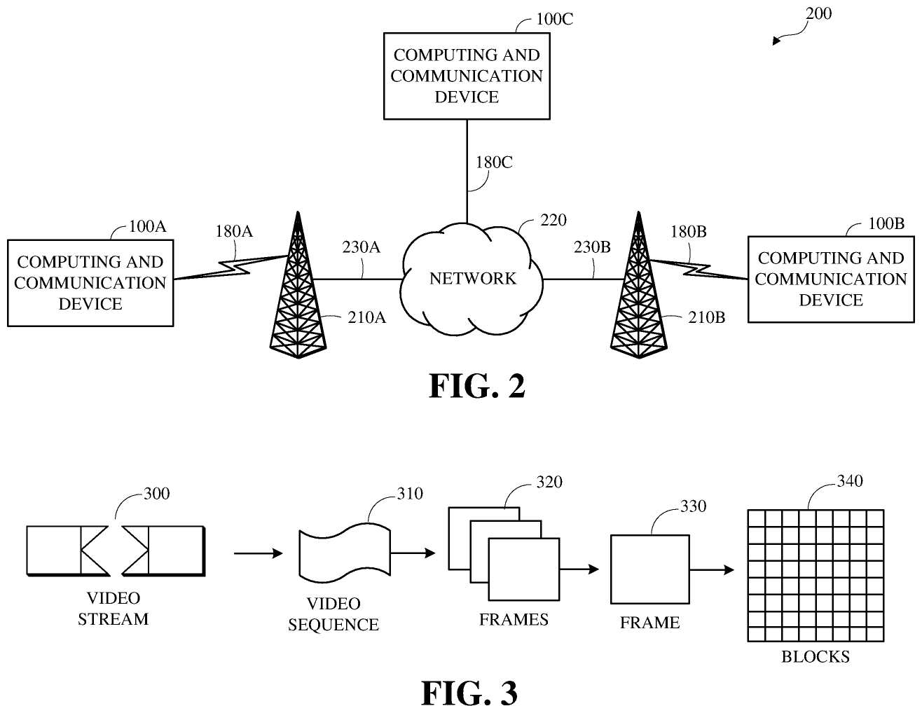

FIG. 2 is a diagram of a computing and communications system 200 in accordance with implementations of this disclosure. The computing and communications system 200 shown includes computing and communication devices 100A, 100B, 100C, access points 210A, 210B, and a network 220. For example, the computing and communications system 200 can be a multiple access system that provides communication, such as voice, audio, data, video, messaging, broadcast, or a combination thereof, to one or more wired or wireless communicating devices, such as the computing and communication devices 100A, 100B, 100C. Although, for simplicity, FIG. 2 shows three computing and communication devices 100A, 100B, 100C, two access points 210A, 210B, and one network 220, any number of computing and communication devices, access points, and networks can be used.

A computing and communication device 100A, 100B, or 100C can be, for example, a computing device, such as the computing device 100 shown in FIG. 1. For example, the computing and communication devices 100A, 100B may be user devices, such as a mobile computing device, a laptop, a thin client, or a smartphone, and the computing and communication device 100C may be a server, such as a mainframe or a cluster. Although the computing and communication device 100A and the computing and communication device 100B are described as user devices, and the computing and communication device 100C is described as a server, any computing and communication device may perform some or all of the functions of a server, some or all of the functions of a user device, or some or all of the functions of a server and a user device. For example, the server computing and communication device 100C may receive, encode, process, store, transmit, or a combination thereof, audio data; and one or both of the computing and communication device 100A and the computing and communication device 100B may receive, decode, process, store, present, or a combination thereof, the audio data.

Each computing and communication device 100A, 100B, 100C, which may include a user equipment (UE), a mobile station, a fixed or mobile subscriber unit, a cellular telephone, a personal computer, a tablet computer, a server, consumer electronics, or any similar device, can be configured to perform wired or wireless communication, such as via the network 220. For example, the computing and communication devices 100A, 100B, 100C can be configured to transmit or receive wired or wireless communication signals. Although each computing and communication device 100A, 100B, 100C is shown as a single unit, a computing and communication device can include any number of interconnected elements.

Each access point 210A, 210B can be any type of device configured to communicate with a computing and communication devices 100A, 100B, 100C, a network 220, or both via wired or wireless communication links 180A, 180B, 180C. For example, an access point 210A, 210B can include a base station, a base transceiver station (BTS), a Node-B, an enhanced Node-B (eNode-B), a Home Node-B (HNode-B), a wireless router, a wired router, a hub, a relay, a switch, or any similar wired or wireless device. Although each access point 210A, 210B is shown as a single unit, an access point can include any number of interconnected elements.

The network 220 can be any type of network configured to provide services, such as voice, data, applications, voice over internet protocol (VoIP), or any other communications protocol or combination of communications protocols, over a wired or wireless communication link. For example, the network 220 can be a local area network (LAN), wide area network (WAN), virtual private network (VPN), a mobile or cellular telephone network, the Internet, or any other means of electronic communication. The network can use a communication protocol, such as the Transmission Control Protocol (TCP), the User Datagram Protocol (UDP), the Internet Protocol (IP), the Real-time Transport Protocol (RTP), the HyperText Transport Protocol (HTTP), or a combination thereof.

The computing and communication devices 100A, 100B, 100C can communicate with each other via the network 220 using one or more wired or wireless communication links, or via a combination of wired and wireless communication links. For example, as shown, the computing and communication devices 100A, 100B can communicate via wireless communication links 180A, 180B, and computing and communication device 100C can communicate via a wired communication link 180C. Any of the computing and communication devices 100A, 100B, 100C may communicate using any wired or wireless communication link or links. For example, a first computing and communication device 100A can communicate via a first access point 210A using a first type of communication link, a second computing and communication device 100B can communicate via a second access point 210B using a second type of communication link, and a third computing and communication device 100C can communicate via a third access point (not shown) using a third type of communication link. Similarly, the access points 210A, 210B can communicate with the network 220 via one or more types of wired or wireless communication links 230A, 230B. Although FIG. 2 shows the computing and communication devices 100A, 100B, 100C in communication via the network 220, the computing and communication devices 100A, 100B, 100C can communicate with each other via any number of communication links, such as a direct wired or wireless communication link.

In some implementations, communications between one or more of the computing and communication devices 100A, 100B, 100C may omit communicating via the network 220 and may include transferring data via another medium (not shown), such as a data storage device. For example, the server computing and communication device 100C may store audio data, such as encoded audio data, in a data storage device, such as a portable data storage unit, and one or both of the computing and communication device 100A or the computing and communication device 100B may access, read, or retrieve the stored audio data from the data storage unit, such as by physically disconnecting the data storage device from the server computing and communication device 100C and physically connecting the data storage device to the computing and communication device 100A or the computing and communication device 100B.

Other implementations of the computing and communications system 200 are possible. For example, in an implementation, the network 220 can be an ad-hoc network and can omit one or more of the access points 210A, 210B. The computing and communications system 200 may include devices, units, or elements not shown in FIG. 2. For example, the computing and communications system 200 may include many more communicating devices, networks, and access points.

FIG. 3 is a diagram of a video stream 300 for use in encoding and decoding in accordance with implementations of this disclosure. A video stream 300, such as a video stream captured by a video camera or a video stream generated by a computing device, may include a video sequence 310. The video sequence 310 may include a sequence of adjacent frames 320. Although three adjacent frames 320 are shown, the video sequence 310 can include any number of adjacent frames 320.

Each frame 330 from the adjacent frames 320 may represent a single image from the video stream. Although not shown in FIG. 3, a frame 330 may include one or more segments, tiles, or planes, which may be coded, or otherwise processed, independently, such as in parallel. A frame 330 may include blocks 340. Although not shown in FIG. 3, a block can include pixels. For example, a block can include a 16×16 group of pixels, an 8×8 group of pixels, an 8×16 group of pixels, or any other group of pixels. Unless otherwise indicated herein, the term “block” can include a superblock, a macroblock, a segment, a slice, or any other portion of a frame. A frame, a block, a pixel, or a combination thereof, can include display information, such as luminance information, chrominance information, or any other information that can be used to store, modify, communicate, or display the video stream or a portion thereof.

In some implementations, a frame that is not part of a video stream is encoded and decoded in accordance with implementations of this disclosure.

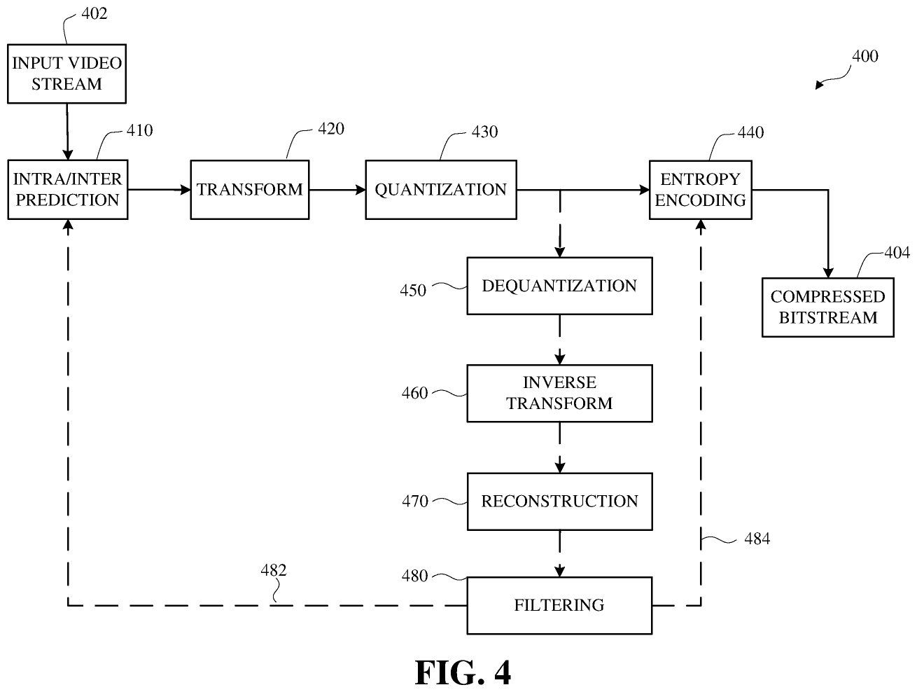

FIG. 4 is a block diagram of an encoder 400 in accordance with implementations of this disclosure. Encoder 400 can be implemented in a device, such as the computing device 100 shown in FIG. 1 or the computing and communication devices 100A, 100B, 100C shown in FIG. 2, as, for example, a computer software program stored in a data storage unit, such as the memory 110 shown in FIG. 1. The computer software program can include machine-readable instructions that may be executed by a processor, such as the processor 120 shown in FIG. 1, and may cause the device to encode video data as described herein. The encoder 400 can be implemented as specialized hardware included, for example, in the computing device 100.

The encoder 400 can encode an input video stream 402, such as the video stream 300 shown in FIG. 3, to generate an encoded (compressed) bitstream 404. In some implementations, the encoder 400 may include a forward path for generating the compressed bitstream 404. The input video stream 402 can be a single image or a collection of images. The forward path may include an intra/inter prediction unit 410, a transform unit 420, a quantization unit 430, an entropy encoding unit 440, or any combination thereof. In some implementations, the encoder 400 may include a reconstruction path (indicated by the broken connection lines) to reconstruct a frame for encoding of further blocks. The reconstruction path may include a dequantization unit 450, an inverse transform unit 460, a reconstruction unit 470, a filtering unit 480, or any combination thereof. Other structural variations of the encoder 400 can be used to encode the video stream 402.

For encoding the video stream 402, each frame within the video stream 402 can be processed in units of blocks. Thus, a current block may be identified from the blocks in a frame, and the current block may be encoded.

At the intra/inter prediction unit 410, the current block can be encoded using either intra-frame prediction, which may be within a single frame, or inter-frame prediction, which may be from frame to frame. Intra-prediction may include generating a prediction block from samples in the current frame that have been previously encoded and reconstructed. Inter-prediction may include generating a prediction block from samples in one or more previously constructed reference frames. Generating a prediction block for a current block in a current frame may include performing motion estimation to generate a motion vector indicating an appropriate reference portion of the reference frame. In the case of encoding a single image (e.g., an image that is not part of a video sequence and/or a sequence of images), the intra/inter prediction unit 410 can encode the image using intra-frame prediction.

The intra/inter prediction unit 410 may subtract the prediction block from the current block (raw block) to produce a residual block. The transform unit 420 may perform a block-based transform, which may include transforming the residual block into transform coefficients in, for example, the frequency domain. Examples of block-based transforms include the Karhunen-Loève Transform (KLT), the Discrete Cosine Transform (DCT), the Singular Value Decomposition Transform (SVD), the Fourier transform (FT), the Discrete Sine Transform (DST), and the Asymmetric Discrete Sine Transform (ADST). In an example, the DCT may include transforming a block into the frequency domain. The DCT may include using transform coefficient values based on spatial frequency, with the lowest frequency (i.e., DC) coefficient at the top-left of the matrix and the highest frequency coefficient at the bottom-right of the matrix.

The quantization unit 430 may convert the transform coefficients into discrete quantum values, which may be referred to as quantized transform coefficients or quantization levels. The quantized transform coefficients can be entropy encoded by the entropy encoding unit 440 to produce entropy-encoded coefficients. Entropy encoding can include using a probability distribution metric. The entropy-encoded coefficients and information used to decode the block, which may include the type of prediction used, motion vectors, and quantizer values, can be output to the compressed bitstream 404. The compressed bitstream 404 can be formatted using various techniques, such as run-length encoding (RLE) and zero-run coding.

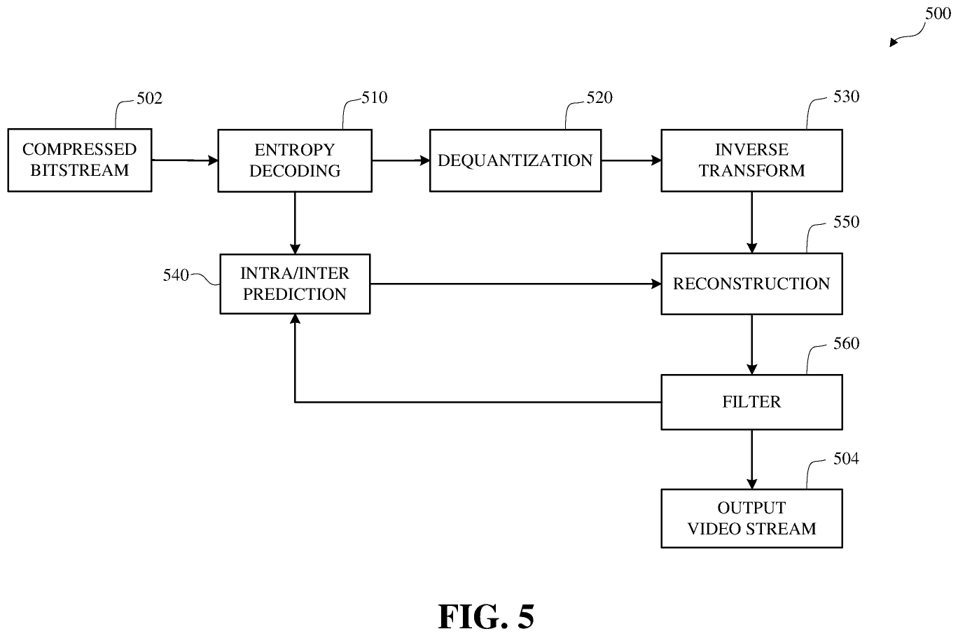

The reconstruction path can be used to maintain reference frame synchronization between the encoder 400 and a corresponding decoder, such as the decoder 500 shown in FIG. 5. The reconstruction path may be similar to the decoding process discussed below and may include decoding the encoded frame, or a portion thereof, which may include decoding an encoded block, which may include dequantizing the quantized transform coefficients at the dequantization unit 450 and inverse transforming the dequantized transform coefficients at the inverse transform unit 460 to produce a derivative residual block. The reconstruction unit 470 may add the prediction block generated by the intra/inter prediction unit 410 to the derivative residual block to create a decoded block. The filtering unit 480 can be applied to the decoded block to generate a reconstructed block, which may reduce distortion, such as blocking artifacts. Although one filtering unit 480 is shown in FIG. 4, filtering the decoded block may include loop filtering, deblocking filtering, or other types of filtering or combinations of types of filtering. The reconstructed block may be stored or otherwise made accessible as a reconstructed block, which may be a portion of a reference frame, for encoding another portion of the current frame, another frame, or both, as indicated by the broken line at 482. Coding information, such as deblocking threshold index values, for the frame may be encoded, included in the compressed bitstream 404, or both, as indicated by the broken line at 484.

Other variations of the encoder 400 can be used to encode the compressed bitstream 404. For example, a non-transform based encoder 400 can quantize the residual block directly without the transform unit 420. In some implementations, the quantization unit 430 and the dequantization unit 450 may be combined into a single unit.

FIG. 5 is a block diagram of a decoder 500 in accordance with implementations of this disclosure. The decoder 500 can be implemented in a device, such as the computing device 100 shown in FIG. 1 or the computing and communication devices 100A, 100B, 100C shown in FIG. 2, as, for example, a computer software program stored in a data storage unit, such as the memory 110 shown in FIG. 1. The computer software program can include machine-readable instructions that may be executed by a processor, such as the processor 120 shown in FIG. 1, and may cause the device to decode video data as described herein. The decoder 500 can be implemented as specialized hardware included, for example, in the computing device 100.

The decoder 500 may receive a compressed bitstream 502, such as the compressed bitstream 404 shown in FIG. 4, and may decode the compressed bitstream 502 to generate an output video stream 504. The decoder 500 may include an entropy decoding unit 510, a dequantization unit 520, an inverse transform unit 530, an intra/inter prediction unit 540, a reconstruction unit 550, a filtering unit 560, or any combination thereof. Other structural variations of the decoder 500 can be used to decode the compressed bitstream 502.

The entropy decoding unit 510 may decode data elements within the compressed bitstream 502 using, for example, Context Adaptive Binary Arithmetic Decoding, to produce a set of quantized transform coefficients. The dequantization unit 520 can dequantize the quantized transform coefficients, and the inverse transform unit 530 can inverse transform the dequantized transform coefficients to produce a derivative residual block, which may correspond to the derivative residual block generated by the inverse transform unit 460 shown in FIG. 4. Using header information decoded from the compressed bitstream 502, the intra/inter prediction unit 540 may generate a prediction block corresponding to the prediction block created in the encoder 400. At the reconstruction unit 550, the prediction block can be added to the derivative residual block to create a decoded block. The filtering unit 560 can be applied to the decoded block to reduce artifacts, such as blocking artifacts, which may include loop filtering, deblocking filtering, or other types of filtering or combinations of types of filtering, and which may include generating a reconstructed block, which may be output as the output video stream 504.

Other variations of the decoder 500 can be used to decode the compressed bitstream 502. For example, the decoder 500 can produce the output video stream 504 without the deblocking filtering unit 570.

As mentioned above, in implementations according to this disclosure, coding types of symbols can be dynamically specified rather than being pre-determined and agreed upon between an encoder and decoder.

To illustrate, at encoding time, all the symbol values (i.e., all occurrences) of a symbol will be known. Thus, if the encoder determines that the symbol values are random (i.e., are equi-probable), then, a coding type indicating that the values of the symbol are to be decoded using a range may have a better compression performance than encoding the values using probabilities because the probabilities would not need to be stored. On the other hand, if the probabilities are meaningful, then a coding type using a dictionary may be more optimal. Such processing at an encoder can provide for more encoding flexibility and results in better compression.

As another example, the respective statistics of different symbols for a small image (e.g., a 10×10 logo), for a larger image (e.g., a 1024×1024 image), or for a black-and-white image may be very different. Thus, encoding the symbols for each such image using the same pre-specific coding types can result in wasted bits in the respective compressed bitstreams. However, adapting the coding types to the statistics, even when accounting for additional overhead bits (i.e., bits in the header for indicating the coding types and/or respective parameters, if applicable), can result in better compression performance.

As another example, assume that a symbol represents quantized transform coefficients. At very low encoding qualities, the coefficients for the color channels (e.g., the U or the V chroma channels) can be very small and they are often zero. In such cases, it may be more useful (e.g., optimal, etc.) to code the quantized transform coefficients using a range because all the coefficients will be in, for example, the range [0,2]. On the other hand, at higher encoding qualities or for the Y luminance channel, the coefficients can have a lot of variability and magnitudes where, however, smaller coefficient values are more frequent. In such a case, coding the values using a variable-number-of-bits coding type (e.g., using probabilities and/or a dictionary) may be more useful.

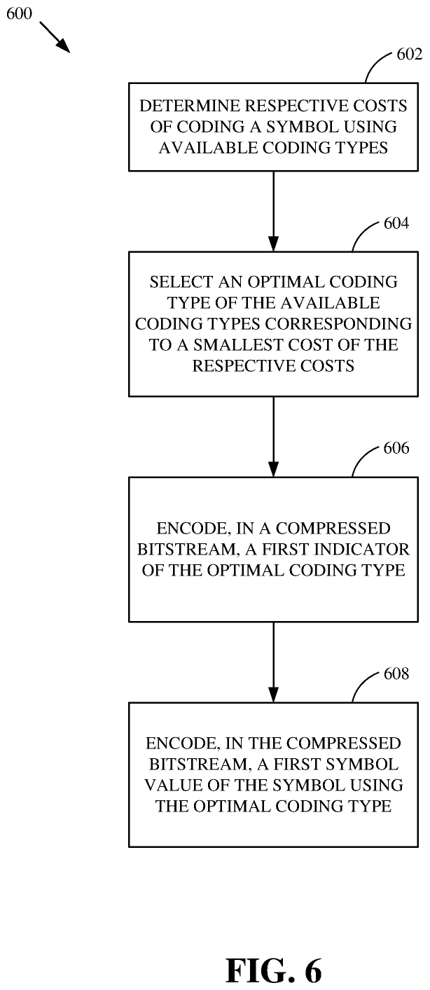

FIG. 6 is an example of a flowchart of a technique 600 for encoding symbols into a compressed bitstream according to implementations of this disclosure. As mentioned above, the symbols can represent any aspect of media data. The media data can be an image, an audio clip, a text document, or any other media data.

The technique 600 can be implemented, for example, as a software program that may be executed by computing and communication devices such as one of the computing and communication devices 100A, 100B, 100C of FIG. 2. The software program can include machine-readable instructions that may be stored in a memory such as the memory 110 of FIG. 1, and that, when executed by a processor, such as the processor 120 of FIG. 1, can cause the computing and communication device to perform the technique 600. In an example, the media data is an image that can be encoded by an encoder, such as the encoder 400 of FIG. 4. The technique 600 can be implemented in whole or in part in the entropy encoding unit 440 of the encoder 400 of FIG. 4. The technique 600 can be implemented using specialized hardware or firmware. Multiple processors, memories, or both, may be used.

For example, the encoder 400 can encode the image as described above with respect to FIG. 4. However before writing the compressed image data to the compressed bitstream 404 of FIG. 4, the technique 600 determines which encoding type to use for at least some of the symbols.

At 602, the technique 600 determines respective costs of coding a symbol using available coding types. The coding types can include at least some of the coding types described above. The coding types can include other coding types. At least some of the coding types can be fixed-number-of-bits coding types. At least some of the coding types can be variable-number-of-bits coding types. In an example, the coding types include a first coding type and a second coding type. The first coding type indicates that a value of the symbol is to be decoded using a same number of bits. The second coding type indicates that a value of the symbol is to be decoded using a range.

For a given coding type, the technique 600 encodes all the symbol values of the symbol using the given coding type. The cost can be the number of bits required to code the values using the given coding type. The cost can include the cost of any additional bits required to indicate the coding type in the bitstream and any additional parameters required for the coding type.

At 604, the technique 600 selects an optimal coding type of the available coding types. The optimal coding type corresponds to a smallest cost of the respective costs.

At 606, the technique 600 encodes, in the compressed bitstream, a first indicator of the optimal coding type. For example, assuming that there are n available coding types, each of the coding types can be indicated (e.g., coded) using ceiling(log₂(n)) bits, where ceiling(x) is the lowest integer that is greater than or equal to.

In an example, the coding types can include four coding types. In addition to the first coding type and the second type, the available coding types can include a coding type for coding using static or updatable probabilities that are defined in a histogram of the symbol values and a coding type for coding using a Golomb and/or a Golomb-Rice scheme. Thus, if, for example, there are four available coding types, then each of the available coding types can be indicated using 2 bits.

At 608, the technique 600 encodes, in the compressed bitstream, a first symbol value of the symbol using the optimal coding type.

As mentioned above, a symbol can be encoded using different coding types for different images. Thus, the technique 600 can encode, when encoding an image, a first value of the symbol using a third coding type and can encode, when encoding another image that is different from the image, a second value of the symbol using a fourth coding type that is different from the first coding type.

In an example, selecting the optimal coding type of the available coding types can include determining a probability distribution of values of the symbol; determining a first cost of encoding the values of the symbol using the probability distribution; determining a second cost of encoding the values of the symbol using a specified range; and selecting the one of the encoding the values of the symbol using the probability distribution or encoding the values of the symbol using the specified range based on which of the first cost or the second cost is the optimal coding type.

In an example, encoding, in the compressed bitstream, the first indicator of the optimal coding type can include encoding a second indicator of a probability distribution of the optimal coding type. For example, when encoding a block, the technique 600 can determine whether the block is a smooth block (for example, as consistent with a block of the sky, a whiteboard, the hood of a car, or the like) or a block that contains a lot of texture (for example, as consistent with a block of grass, carpet, or the like). Thus the second indicator can be an indicator of the smoothness of the block. The technique 600 codes the block (e.g., codes a residual block of the block) using a pre-determined probability distribution. The encoder can include (e.g., can have access to, etc.) different pre-determined probability distributions that are associated with respective smoothness levels. The pre-determined probability distribution can be a probability distribution that is associated with a smoothness level that is closest to the smoothness level of the block. A decoder can use the second indicator to decode the block using the pre-determined probability distribution, which would also be included in the decoder.

In an example, the technique 600 can include encoding, in the compressed bitstream, a second symbol value of the symbol using the optimal coding type and encoding, in the compressed bitstream, a flag indicating whether the second symbol value is encoded differentially from the first symbol value. That is, the technique 600 can determine whether to encode the difference of values between two symbol values or whether to code the symbol values themselves. The decision (e.g., determination) of the technique 600 can be indicated in the bitstream using one bit in the header. The bit can indicate whether values of the symbol are encoded sequentially or differentially. Differential coding can be useful when the symbol values are close in value. On the other hand, when the values are not close, then sequential coding may be used.

For some images, it may be too costly to encode the distribution (e.g., probabilities) of the color values of the pixels of the image or a block of the image and coding the color values may be more efficient. In an example, the image can be a pre-multiplied image having an alpha value and the symbol can be representative of a color channel value of a pixel of the image. A pre-multiplied image is one where the alpha channel (i.e., the transparency) is already applied to the red, green, and blue color channels. In such an example, the technique 600 can include encoding, in the compressed bitstream, of the alpha value as a maximum value of a specified range for decoding the symbol. The alpha value can be encoded as a parameter of the coding type. Assuming, for illustration purposes only, that the color values are each in the range of [0, 255] and that the alpha value is 128, in the pre-multiplied image, no pixel color value can exceed the alpha value, 128. Thus, the coding type can be a range coding type where the upper bound of the range (e.g., [0, 128]) is the alpha value.

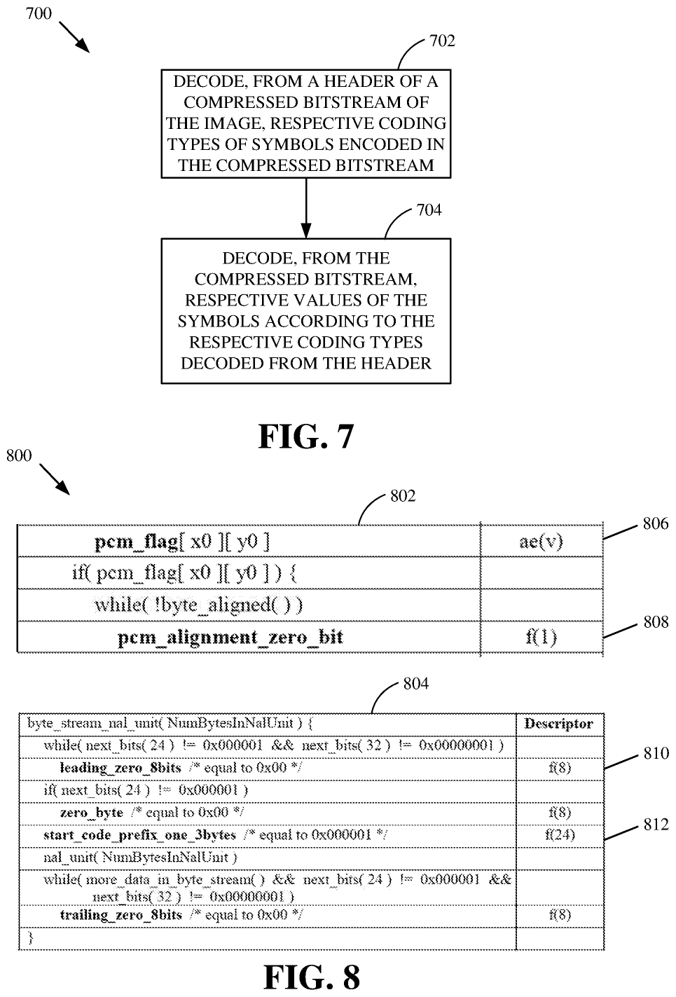

FIG. 7 is an example of a flowchart of a technique 700 for decoding symbols according to implementations of this disclosure. As mentioned above, the symbols can represent any aspect of media data. The media data can be an image, an audio clip, a text document, or any other media data. In an example, the technique 700 can be used to decode an image.

The technique 700 can be implemented, for example, as a software program that may be executed by computing and communication devices such as one of the computing and communication devices 100A, 100B, 100C of FIG. 2. The software program can include machine-readable instructions that may be stored in a memory such as the memory 110 of FIG. 1, and that, when executed by a processor, such as the processor 120 of FIG. 1, can cause the computing and communication device to perform the technique 700. In an example, the media data is an image that can be decoded by a decoder, such as the decoder 500 of FIG. 5. The technique 700 can be implemented in whole or in part in the entropy decoding unit 510 of the decoder 500 of FIG. 5. The technique 700 can be implemented using specialized hardware or firmware. Multiple processors, memories, or both, may be used.

At 702, the technique 700 decodes, from a header of a compressed bitstream of the image, respective coding types of symbols encoded in the compressed bitstream. The coding types can be as described above.

Decoding the respective coding types can mean decoding respective indications of the coding types. For example, as described above, in a case where four coding types are available, each of the coding types can be indicated with two bits. As described above, a coding type indicates how a value of a symbol encoded according to the respective coding type is to be decoded by the technique 700.

In an example, the coding types include a first coding type and a second coding type. The first coding type indicates that the value of the symbol is to be decoded using a same number of bits. The second coding type indicates that the value of the symbol is to decoded using a range. The coding types can be arranged in the header according to a predetermined order. The position of a coding type indicates which symbol the coding type corresponds to.

In an example, the header can be the header of the compressed bitstream as whole. In another example, the header can be the header of a largest coding unit. In an example, the header can be the header of a coding block. For example, for a symbol indicating a size of the image, the respective coding type can be indicated in the header of the compressed bitstream. For example, with respect to a quantized transform block, the coding type of the quantized transform coefficients can be indicated in the header of the quantized transform block. In an example, coding types can be included in the header of the compressed bitstream and at least some of the coding types can be overridden in different headers. For example, the compressed bitstream can include a default coding type of quantized transform coefficients. However, the default coding type can be overridden in the header of a particular quantized transform block.

At 704, the technique 700 reconstructs the image by decoding, from the compressed bitstream, respective values of the symbols according to the respective coding types decoded from the header.

Thus, for a given symbol, the technique 700 reads the coding type of the symbol from the header. Depending on the coding type, and as described above, the technique 700 can read from the header extra data (i.e., parameters) for the coding type. For example, if a symbol is to be read (i.e., decoded) using a fixed number of bits, then the technique 700 can read a number that is the fixed number of bits. For example, if the symbol is to be read using a range, then the technique 700 can read the range. For example, if a symbol is to be read using probabilities in a dictionary, the technique 700 can read the probabilities, or as described above, the technique 700 can read an indication of the probabilities.

Thus, in an example, the technique 700 can include decoding, from the compressed bitstream, a number of the same number of bits and decoding a symbol value using the number of the same number of bits. In an example, the respective coding types can include a third type indicating that the value of the symbol is to be decoded using probabilities in a dictionary.

In an example, the image can be a pre-multiplied image, as described above. Thus, the technique 700 can include decoding, from the compressed bitstream, the range where a maximum value of the range is an alpha-channel value of the image and decoding a color value of a pixel using the range. The color value can be one of a red, green, blue color channel value, or some other color channel value.

An illustration of the technique 600 and the technique 700 is now described with respect to decoding a color value of a pixel of an image. If the image is small (e.g., in dimensions or in size in bytes), the technique 600 may determine that it is better to encode, and for the technique 700 to read, the color value over 8 or 10 bits, whatever the bit depth may be, as it does not create a bit header overhead. If the image is large, the technique 600 may determine that it is optimal to store, and for the technique 700 to read, the color value using the overall statistics. Thus, the probabilities from a histogram can be used to code the color value. In some situations, storing the statistics is impractical, such as when, for example, the image is relatively small as compared to the statistics (e.g., bits to convey the statistics) to be stored. Thus, if storing the probabilities leads to sub-optimal coding and the image is a pre-multiplied image, which means that the RGB values cannot be bigger than alpha, then it may be more optimal to store the color value as a value in the range [0, alpha]. If the image is very dark, then the distribution of the color value may be peaked in 0 with a long tail. Thus, Golomb coding becomes more efficient for storing the color values.

Another coding type that can be available is the trivial coding type. The trivial coding type can be used when the symbol can only appear with one given value. As such, the probability of the value is 1 (i.e., 100%). For example, assume that for a given image that is known to include transparency, all the values of the transparency are 255. This in turn means that the image includes no alpha or, equivalently, that the alpha value is always 255 (given an 8 bit representation of color values). Thus, the symbol for alpha transparency can be encoded as a trivial coding type. A parameter of the trivial coding type can be the trivial value (e.g., the trivial value 255).

For simplicity of explanation, the technique 600 and the technique 700 of FIGS. 6 and 7, respectively, are depicted and described as series of steps or operations. However, the steps or operations in accordance with this disclosure can occur in various orders and/or concurrently. Additionally, other steps or operations not presented and described herein may be used. Furthermore, not all illustrated steps or operations may be required to implement a method in accordance with the disclosed subject matter.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise or clear from context, “X includes A or B” is intended to mean any of the natural inclusive permutations thereof. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an implementation” or “one implementation” throughout is not intended to mean the same embodiment or implementation unless described as such. As used herein, the terms “determine” and “identify,” or any variations thereof, include selecting, ascertaining, computing, looking up, receiving, determining, establishing, obtaining, or otherwise identifying or determining in any manner whatsoever using one or more of the devices shown in FIG. 1.

Further, for simplicity of explanation, although the figures and descriptions herein may include sequences or series of operations or stages, elements of the methods disclosed herein can occur in various orders and/or concurrently. Additionally, elements of the methods disclosed herein may occur with other elements not explicitly presented and described herein. Furthermore, one or more elements of the methods described herein may be omitted from implementations of methods in accordance with the disclosed subject matter.

The implementations of the transmitting computing and communication device 100A and/or the receiving computing and communication device 100B (and the algorithms, methods, instructions, etc., stored thereon and/or executed thereby) can be realized in hardware, software, or any combination thereof. The hardware can include, for example, computers, intellectual property (IP) cores, application-specific integrated circuits (ASICs), programmable logic arrays, optical processors, programmable logic controllers, microcode, microcontrollers, servers, microprocessors, digital signal processors, or any other suitable circuit. In the claims, the term “processor” should be understood as encompassing any of the foregoing hardware, either singly or in combination. The terms “signal” and “data” are used interchangeably. Further, portions of the transmitting computing and communication device 100A and the receiving computing and communication device 100B do not necessarily have to be implemented in the same manner.

Further, in one implementation, for example, the transmitting computing and communication device 100A or the receiving computing and communication device 100B can be implemented using a computer program that, when executed, carries out any of the respective methods, algorithms, and/or instructions described herein. In addition or alternatively, for example, a special-purpose computer/processor, which can contain specialized hardware for carrying out any of the methods, algorithms, or instructions described herein, can be utilized.

The transmitting computing and communication device 100A and the receiving computing and communication device 100B can, for example, be implemented on computers in a real-time video system. Alternatively, the transmitting computing and communication device 100A can be implemented on a server, and the receiving computing and communication device 100B can be implemented on a device separate from the server, such as a hand-held communications device. In this instance, the transmitting computing and communication device 100A can encode content using an encoder 400 into an encoded video signal and transmit the encoded video signal to the communications device. In turn, the communications device can then decode the encoded video signal using a decoder 500. Alternatively, the communications device can decode content stored locally on the communications device, for example, content that was not transmitted by the transmitting computing and communication device 100A. Other suitable transmitting computing and communication device 100A and receiving computing and communication device 100B implementation schemes are available. For example, the receiving computing and communication device 100B can be a generally stationary personal computer rather than a portable communications device, and/or a device including an encoder 400 may also include a decoder 500.

Further, all or a portion of implementations can take the form of a computer program product accessible from, for example, a tangible computer-usable or computer-readable medium. A computer-usable or computer-readable medium can be any device that can, for example, tangibly contain, store, communicate, or transport the program for use by or in connection with any processor. The medium can be, for example, an electronic, magnetic, optical, electromagnetic, or semiconductor device. Other suitable mediums are also available. The above-described implementations have been described in order to allow easy understanding of the application and are not limiting. On the contrary, the application covers various modifications and equivalent arrangements included within the scope of the appended claims, which scope is to be accorded the broadest interpretation as is permitted under the law so as to encompass all such modifications and equivalent arrangements.

1. A method of encoding symbols representing information of an image, comprising:
determining respective costs of coding a symbol using available coding types, wherein:
the available coding types include a first coding type and a second coding type,
the first coding type indicates that a value of the symbol is to be decoded using a same number of bits, and
the second coding type indicates that the value of the symbol is to be decoded using a range;
selecting an optimal coding type of the available coding types, wherein the optimal coding type corresponds to a smallest cost of the respective costs;
encoding, in a compressed bitstream, a first indicator of the optimal coding type; and
encoding, in the compressed bitstream, a first symbol value of the symbol using the optimal coding type.

2. The method of claim 1, further comprising:
encoding, when encoding the image, a first value of the symbol using a third coding type; and
encoding, when encoding another image that is different from the image, a second value of the symbol using a fourth coding type that is different from the first coding type.

3. The method of claim 1, wherein selecting the optimal coding type of the available coding types comprises:
determining a probability distribution of values of the symbol;
determining a first cost of encoding the values of the symbol using the probability distribution;
determining a second cost of encoding the values of the symbol using a specified range; and
selecting one of the encoding the values of the symbol using the probability distribution or encoding the values of the symbol using the specified range based on which of the first cost or the second cost is the optimal coding type.

4. The method of claim 1, wherein encoding, in the compressed bitstream, the first indicator of the optimal coding type comprises:
encoding a second indicator of a probability distribution of the optimal coding type.

5. The method of claim 1, wherein selecting the optimal coding type of the available coding types comprises:
determining a first cost of encoding the symbol using a first predetermined probability distribution;
determining a second cost of encoding the symbol using a second predetermined probability distribution; and
selecting one of the first predetermined probability distribution or the second predetermined probability distribution corresponding to a lower cost among the first cost and the second cost.

6. The method of claim 1, further comprising:
encoding, in the compressed bitstream, a second symbol value of the symbol using the optimal coding type; and
encoding, in the compressed bitstream, a flag indicating whether the second symbol value is encoded differentially from the first symbol value.

7. The method of claim 1, wherein:
the image is a pre-multiplied image having an alpha value, and
the symbol is representative of a color channel value of a pixel of the image, the method further comprising:
encoding, in the compressed bitstream, the alpha value as a maximum value of a specified range for decoding the symbol.

8. An apparatus for decoding an image, comprising:
a processor configured to:
decode, from a header of a compressed bitstream of the image, respective coding types of symbols encoded in the compressed bitstream, wherein:
a respective coding type of the respective coding types indicates how a value of a symbol encoded according to the respective coding type is to be decoded,
the respective coding types include a first coding type and a second coding type,
the first coding type indicates that the value of the symbol is to be decoded using a same number of bits, and
the second coding type indicates that the value of the symbol is to be decoded using a range; and
reconstruct the image, including to:
decode, from the compressed bitstream, respective values of the symbols according to the respective coding types decoded from the header.

9. The apparatus of claim 8, wherein the processor is configured to:
decode, from the compressed bitstream, a number of the same number of bits; and
decode a symbol value using the number of the same number of bits.

10. The apparatus of claim 8, wherein the value is a color value of a pixel of the image.

11. The apparatus of claim 8, wherein the processor is configured to:
decode, from the compressed bitstream, the range, wherein a maximum value of the range is an alpha-channel value of the image, and wherein the image is a pre-multiplied image; and
decode a color value of a pixel using the range, wherein the color value is one of a red, green, or blue color channel value.

12. The apparatus of claim 8, wherein the respective coding types further include a third type indicating that the value of the symbol is to be decoded using probabilities in a dictionary.

13. The apparatus of claim 8, wherein the processor is configured to:
decode, from the compressed bitstream, a respective decoding parameter associated with the respective coding type.

14. The apparatus of claim 8, wherein the processor is configured to:
decode, from the compressed bitstream, a specific range associated with the second coding type.

15. The apparatus of claim 8, wherein the processor is configured to:
decode, from the compressed bitstream, a specified number of bits associated with the first coding type.

16. A method of decoding an image from a compressed bitstream, comprising:
decoding, from a header of the compressed bitstream of the image, respective coding types of symbols encoded in the compressed bitstream; and
decoding, from the compressed bitstream, respective values of the symbols according to the respective coding types decoded from the header.

17. The method of claim 16, wherein the respective coding types include a trivial coding type indicating that all symbol values of a symbol of the symbols in the compressed bitstream are a same value.

18. The method of claim 17, further comprising:
decoding the same value from the compressed bitstream.

19. The method of claim 16, wherein the respective coding types comprise at least two of:
a first coding type for decoding first symbol values of a first symbol with a same number of bits;
a second coding type for decoding second symbol values of a second symbol using a range;
a third coding type for decoding third symbol values of a third symbol using probabilities that are defined in a histogram of the symbol values; or
a fourth coding type for decoding fourth symbol values of a fourth symbol using a Golomb scheme.

20. The method of claim 16, wherein the respective coding types include at least one fixed-number-of-bits coding type and at least one variable-number-of-bits coding type.
